(19) United States
(12) Patent Application Publication
(10) Pub. No.: US 2016/0078937 A1
(43) Pub. Date: Mar. 17, 2016

(54) RESISTIVE MEMORY DEVICE AND CONTROL METHOD THEREOF

(71) Applicant: Winbond Electronics Corp., Taichung City (TW)

(72) Inventors: Hsi-Hsien HUNG, Palo Alto, CA (US); Ming-Huei SHIEH, Cupertino, CA (US); Douk Hyoun RYU, San Jose, CA (US)

(21) Appl. No.: 14/487,399

(22) Filed: Sep. 16, 2014

(51) Int. Cl. G11C 13/00

(52) U.S. Cl. CPC G11C 13/0097; G11C 13/0064; G11C 13/0069

(57) ABSTRACT

A resistive memory device is provided. A first cell is coupled to a word line, a first bit line and a source line. A second cell is coupled to the word line, a second bit line and the source line. A control circuit controls the levels of the word line, the first bit line and the source line to execute a set operation for the first cell and execute a reset operation for the second cell. After the set and the reset operations, the resistance of the first cell is less than the resistance of the second cell. During the execution of the set operation, the control circuit asserts the level of the source line at a pre-determined level. During the execution of the reset operation, the control circuit asserts the level of the source line at the pre-determined level.

### BACKGROUND OF THE INVENTION

1. Field of the Invention

The invention relates to a memory device, and more particularly to a resistive memory device.

2. Description of the Related Art

Generally, there are two kinds of computer memory: non-volatile memory and volatile memory. Non-volatile memory comprises Read-only memory (ROM), Programmable Read-Only Memory (PROM), Erasable Programmable Read-Only Memory (EPROM) and flash memory. Volatile memory comprises Dynamic Random Access Memory (DRAM) and Static Random-Access Memory (SRAM).

New kinds of volatile memory comprise ferroelectric memory, Phase-change memory, Magnetoresistive Random Access Memory (MRAM) and Resistive Random Access Memory (RRAM). The RRAMs are widely used as they possess such favorable advantages as having a simple structure, low cost, high speed and low power consumption.

### BRIEF SUMMARY OF THE INVENTION

In accordance with an embodiment, a resistive memory device comprises a first cell, a second cell and a control circuit. The first cell is coupled to a word line, a first bit line and a source line. The second cell is coupled to the word line, a second bit line and the source line. The control circuit controls the levels of the word line, the first bit line and the source line to execute a set operation for the first cell such that the first cell has a first resistance. The control circuit controls the levels of the word line, the second bit line and the source line to execute a reset operation for the second cell such that the second cell has a second resistance that is greater than the first resistance. During the execution of the set operation, the control circuit asserts the level of the source line at a pre-determined level. During the execution of the reset operation, the control circuit asserts the level of the source line at the pre-determined level.

An exemplary embodiment of a control method for a resistive memory device comprising a first cell and a second cell is described in the following. The first cell is coupled to a word line, a first bit line and a source line. The second cell is coupled to the word line, a second bit line and the source line. A set operation is executed such that the first cell has a first resistance. The set operation provides a pre-determined level to the source line. A reset operation is executed such that the second cell has a second resistance higher than the first resistance. The reset operation is to provide the pre-determined level to the source line.

A detailed description is given in the following embodiments with reference to the accompanying drawings.

### BRIEF DESCRIPTION OF THE DRAWINGS

The invention can be more fully understood by referring to the following detailed description and examples with references made to the accompanying drawings, wherein:

FIG. 1 is a schematic diagram of a resistive memory device according to an embodiment of the present invention;

FIG. 2 is a schematic diagram of a cell array according to one embodiment of the present invention;

FIGS. 3A, 3B, 4A and 4B are schematic diagrams of exemplary embodiments of levels of the word lines, the bit lines and the source lines, in accordance with some embodiments;

FIGS. 5A and 5B are flowcharts of exemplary embodiments of a control method, in accordance with some embodiments.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

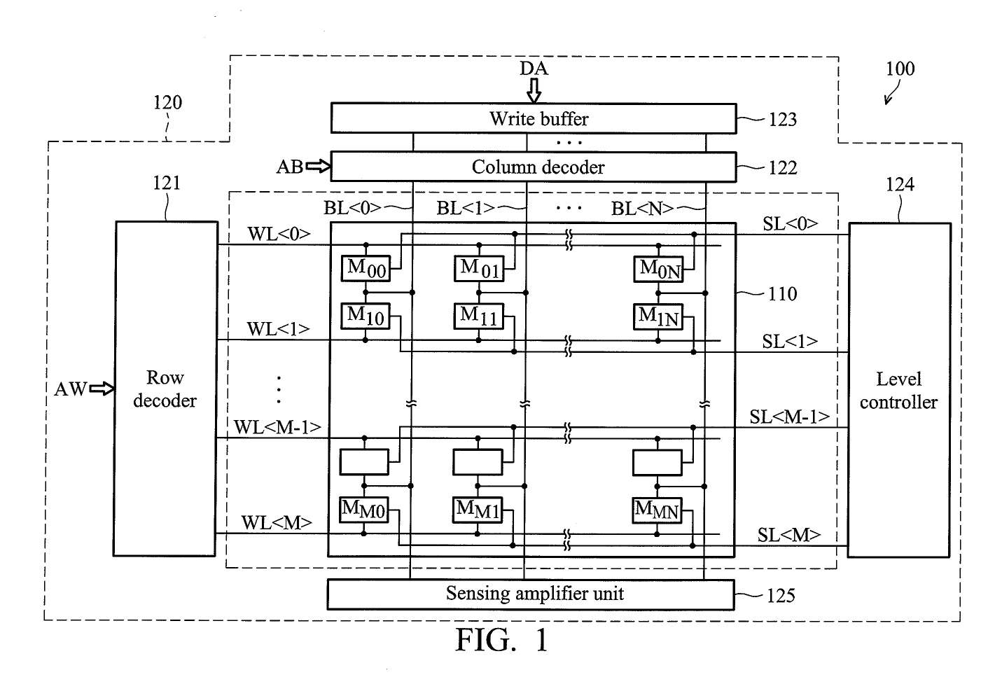

FIG. 1 is a schematic diagram of a resistive memory device according to an embodiment of the present invention. The resistive memory device 100 comprises a cell array 110, a control circuit 120, word lines WL<0>˜WL<M>, bit lines BL<0>˜BL<N> and source lines SL<0>˜SL<M>. The cell array 110 comprises cells M₀₀˜M_{MN}. Each cell is coupled to a corresponding word line, a corresponding bit line, and a corresponding source line. Taking the cells M₀₀ and M₀₁ as an example, the cell M₀₀ is coupled to the word line WL<0>, the bit line BL<0> and the source line SL<0>, and the cell M₀₁ is coupled to the word line WL<0>, the bit line BL<1> and the source line SL<0>.

The control circuit 120 controls the levels of the word lines WL<0>˜WL<M>, bit lines BL<0>˜BL<N> and source lines SL<0>˜SL<M> to access the cells M₀₀˜M_{MN}. For example, in a write mode, the control circuit 120 executes a set operation or a reset operation for the cells M₀₀˜M_{MN} to write data into the cells M₀₀˜M_{MN}, and in a read mode, the control circuit 120 executes a verify operation for the cells M₀₀˜M_{MN} to read the data stored in the cells M₀₀˜M_{MN}.

For example, after the control circuit 120 executes the set operation for a first specific cell, the first specific cell has a low resistance, which means that the data stored in the first specific cell is 0. After the reset operation, a second specific cell has a high resistance. This means that the data stored in the second specific cell is 1. Therefore, the control circuit 120 obtains the data stored in the cells M₀₀˜M_{MN} according to the resistances of the cells M₀₀˜M_{MN}.

In this embodiment, during the executions of the set, reset and verify operations, the control circuit 120 maintains the level of each of the source lines SL<0>˜SL<M> at a pre-determined level. Since the levels of the source lines SL<0>˜SL<M> are fixed at the pre-determined level, the control circuit 120 does not need to change the levels of the source lines SL<0>˜SL<M>. Therefore, the write time when the control circuit 120 writes data into the cells M₀₀˜M_{MN}, is reduced.

In another embodiment, the control circuit 120 simultaneously executes the set and reset operations. For example, the control circuit 120 executes the set operation for the cell M₀₀, meanwhile, the control circuit 120 executes the reset operation for the cell M₀₁. In other embodiments, the control circuit 120 first executes the set operation for the cells M₀₀˜M_{MN} and then executes the reset operation for the cells M₀₀˜M_{MN}.

In this embodiment, the control circuit 120 comprises a row decoder 121, a column decoder 122, a write buffer 123, a level controller 124 and a sensing amplifying unit 125, but the disclosure is not limited thereto. Any circuit structure can serve as the control circuit 120, as long as the circuit structure is capable of controlling the levels of the word lines WL<0>˜WL<M>, the bit lines BL<0>˜BL<N> and the source lines SL<0>˜SL<M>.

The row decoder 121 is coupled to the word lines WL<0>˜WL<M>, decodes the input address AW and turns on at least one word line according to the decoded result. The column decoder 122 is coupled to the bit lines BL<0>˜BL<N>, decodes the input address AB and turns on at least one bit line according to the decoded result. The write buffer 123 writes the input data DA to at least one cell.

The level controller 124 is coupled to the source lines SL<0>˜SL<M> to control the levels of the source lines SL<0>˜SL<M>. In this embodiment, each of the source lines SL<O>˜SL<M> is coupled to the same level controller 124. The invention does not limit the connection relationship between each of the source lines SL<O>˜SL<M> and the level controller. In another embodiment, the source lines SL<O>˜SL<M> are coupled to each other and then coupled to a level controller. In some embodiments, the source lines SL<O>˜SL<M> are divided into various group. Each group is coupled to a corresponding level controller.

The sensing amplifying unit 125 verifies the data stored in the cells M₀₀˜M_{MN} and outputs the data by a parallel-out method or a serial-out method. The invention does not limit how the sensing amplifying unit 125 verifies the cells M₀₀˜M_{MN}. In one embodiment, the sensing amplifying unit 125 utilizes a complement sensing method to verify the data stored in the cells. In this case, each cell comprises a first sub-cell and a second sub-cell. The resistance of the first sub-cell is complemented with the resistance of the second sub-cell. In one embodiment, when the first sub-cell has a low resistance and the second sub-cell has a high resistance, it means that the data stored in the cell is 0. When the first sub-cell has a high resistance and the second sub-cell has a low resistance, it means that the data stored in the cell is 1. Therefore, the data stored in the cell can be identified according to the resistances of the first and second sub-cells.

In another embodiment, the sensing amplifying unit 125 utilizes a reference sensing method to identify the data stored in the cells. In this case, the sensing amplifying unit 125 compares each resistance with a reference resistance and identifies the data stored in the cells according to the compared result.

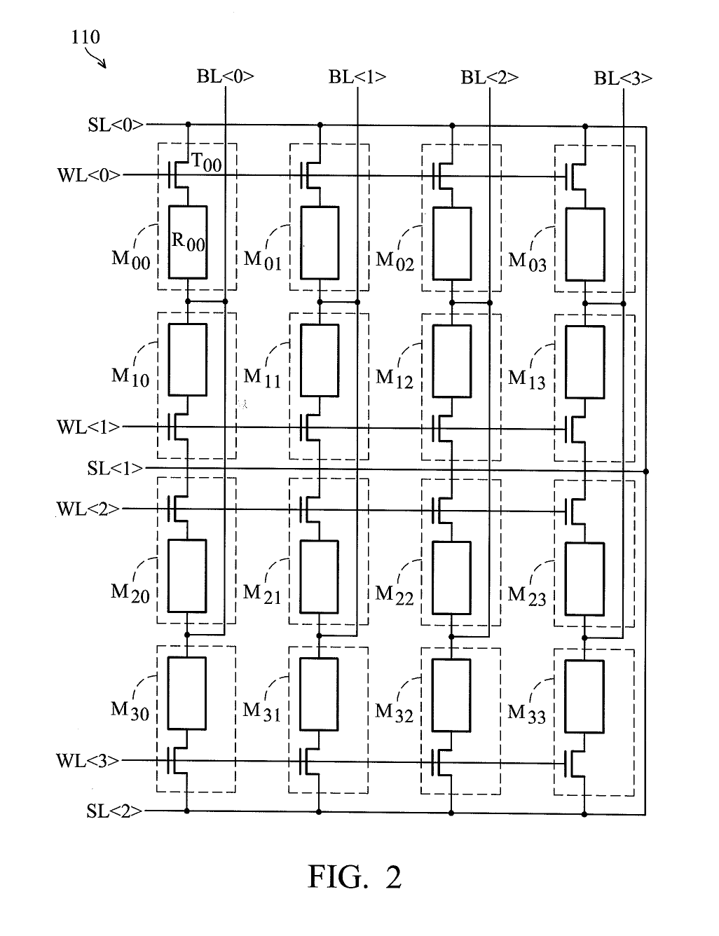

FIG. 2 is a schematic diagram of a cell array according to one embodiment of the present invention. For clarity, FIG. 2 only shows the word lines WL<0>˜WL<3>, the bit lines BL<0>˜BL<3>, the source lines SL<0>˜SL<2>, and cells M₀₀˜M₃₃. In this embodiment, the source lines SL<0>˜SL<2> are coupled to each other.

As shown in FIG. 2, each cell comprises a transistor and a variable resistor. Taking the cell M₀₀ as an example, the gate of the transistor T₀₀ is coupled to the word line WL<0> and a terminal of the transistor T₀₀ is coupled to the source line SL<0>. The variable resistor R₀₀ is coupled between another terminal of the transistor T₀₀ and the bit line BL<0>. In this embodiment, when the control circuit 120 executes the set operation for the cell M₀₀, the variable resistor R₀₀ has a low resistance. When the control circuit 120 executes the reset operation for the cell M₀₀, the variable resistor R₀₀ has a high resistance.

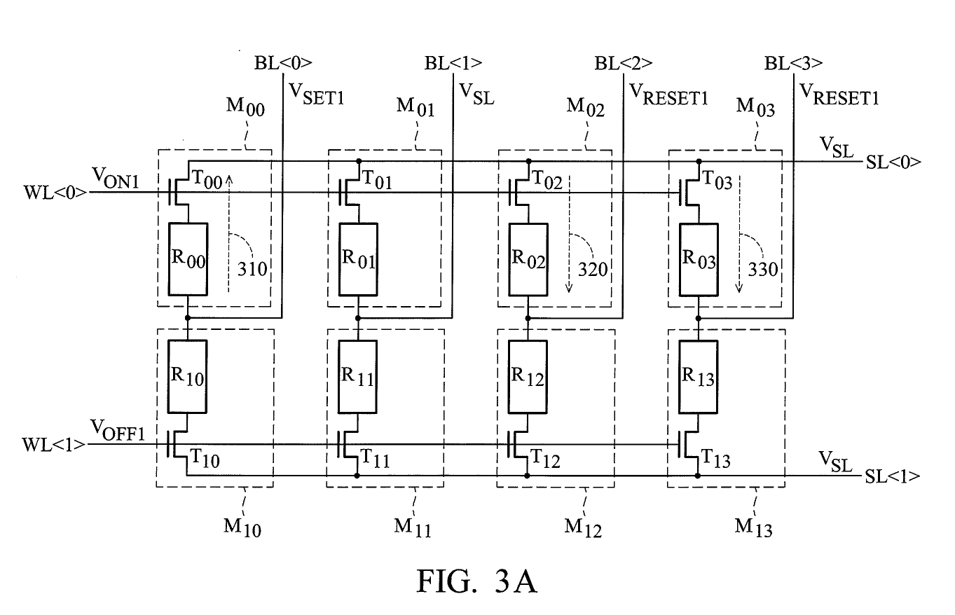

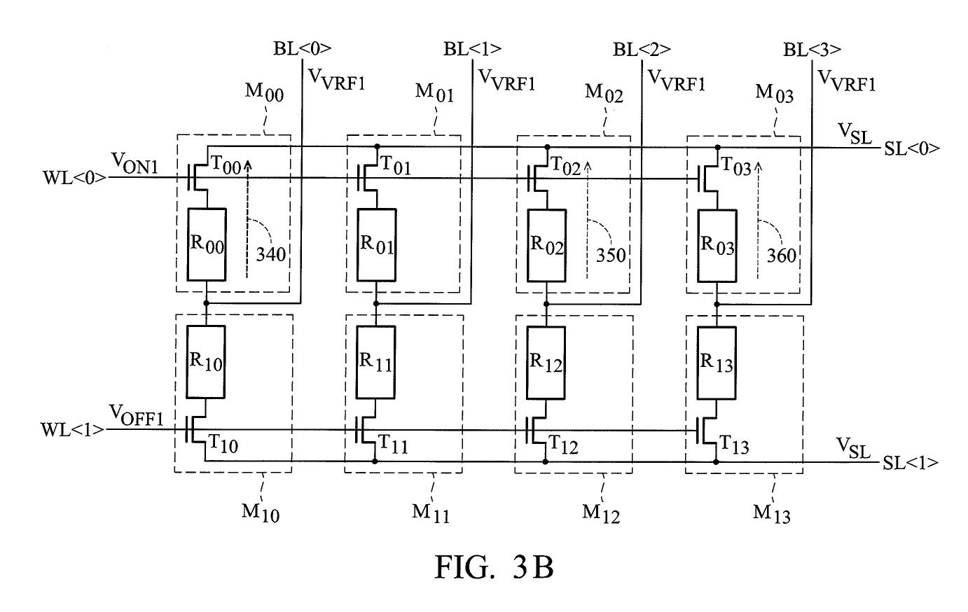

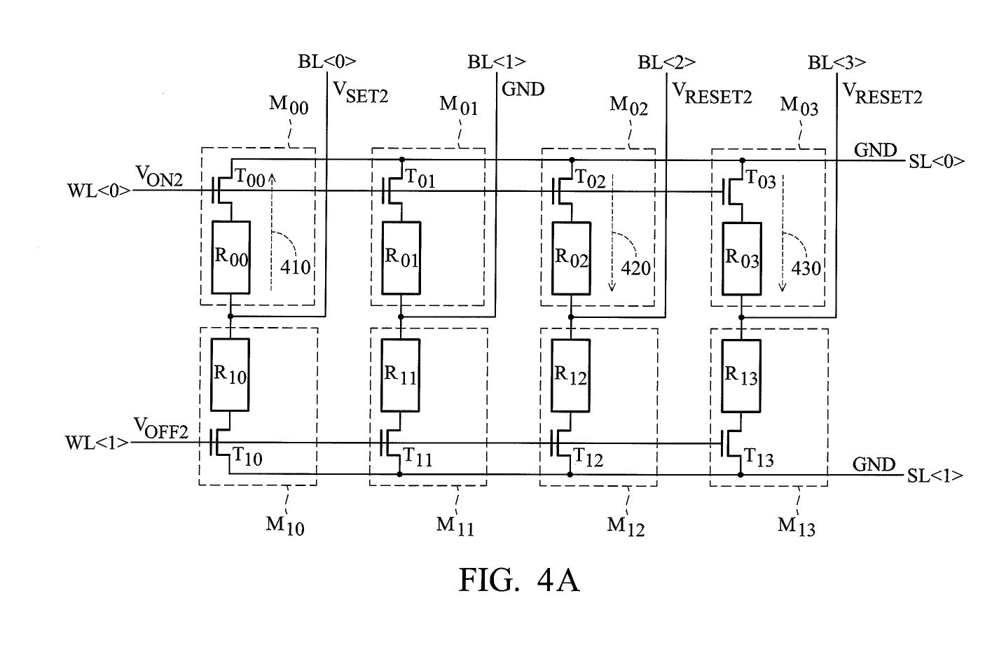

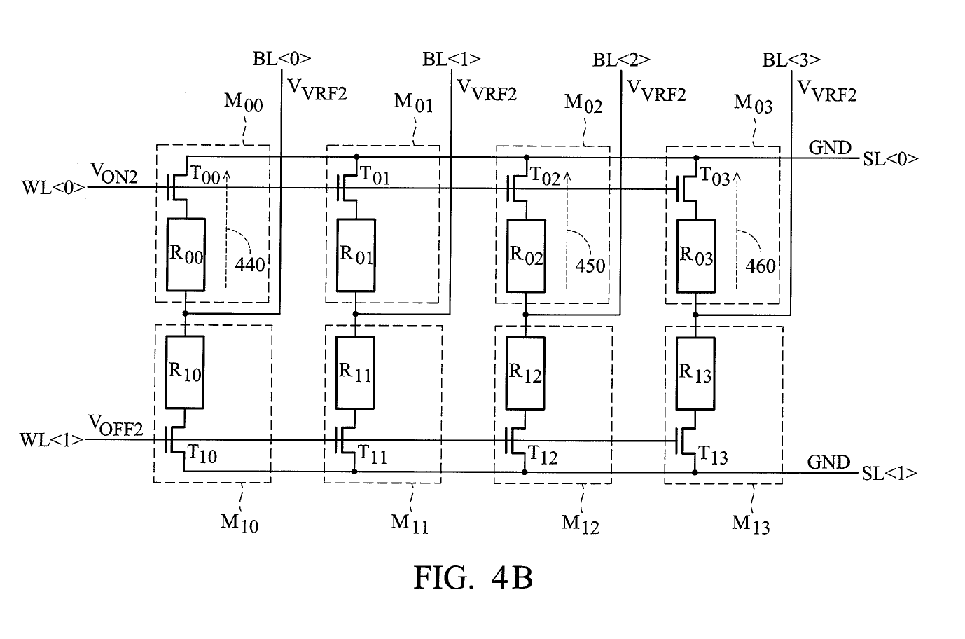

FIGS. 3A, 3B, 4A and 4B are schematic diagrams of exemplary embodiments of levels of the word lines, the bit lines and the source lines, in accordance with some embodiments. For clarity, FIGS. 3A, 3B, 4A and 4B only show cells M₀₀˜M₁₃, the word lines WL<0>˜WL<1>, the bit lines BL<0>˜BL<3> and the source lines SL<0>˜SL<1>.

When the word line WL<0> is at a turn-on level V_{ON1}, the transistors T₀₀˜T₀₃ of the cells M₀₀˜M₀₃ are turned on. Since the word line WL<1> is at a turn-off level V_{OFF1}, the transistors T₁₀˜T₁₃ of the cells M₁₀˜M₁₃ are turned off. In one embodiment, the turn-off level V_{OFF1} is a ground level.

In this embodiment, each of the source lines SL<0> and SL<1> is at a pre-determined level V_{SL}. The bit line BL<0> is at a setting level V_{SET1} and the setting level V_{SET1} is higher than the pre-determined level V_{SL}. Therefore, a current path 310 is formed in the cell M₀₀. Since the current in the current path 310 flows from the variable resistor R₀₀ to the transistor T₀₀, a set operation is executed for the cell M₀₀. After the set operation, the variable resistor R₀₀ has a low resistance. In one embodiment, the data stored in the cell M₀₀ is 0.

In this embodiment, the bit line BL<1> is at the pre-determined level V_{SL}. Since the level of the bit line BL<1> is the same as the level of the source line SL<0>, no current path is formed in the cell M₀₁. Therefore, the set operation and the reset operation are not executed for the cell M₀₁. In other embodiments, if there is no need to execute the set or the reset operation for some cells, the levels of the bit lines coupled to those cells are the same as the levels of the source lines coupled to those cells.

Each of the bit lines BL<2>˜BL<3> is at a reset level V_{RESET1}. In this embodiment, since the reset level V_{RESET1} is less than the pre-determined level V_{SL}, current paths 320 and 330 are formed in the cells M₀₂ and M₀₃. The current in the current path 320 flows from the transistor T₀₂ to the variable resistor R₀₂, the reset operation is executed for the cell M₀₂. Similarly, the reset operation is also executed for the cell M₀₃. After the reset operation, each of the variable resistors R₀₂ and R₀₃ has a high resistance. In this embodiment, the data stored in the cells M₀₂ and M₀₃ are 1.

The invention does not limit the extent of the pre-determined level V_{SL}. In this embodiment, the pre-determined level V_{SL} is between the setting level V_{SET1} and the reset level V_{RESET1}, and the setting level V_{SET1} is higher than the reset level V_{RESET1}. In one embodiment, the reset level V_{RESET1} is ground level. In this case, no negative level is generated. Therefore, the complexity of the resistive memory device is reduced.

In this embodiment, during the executions of the set and the reset operations, the level of the source line SL<0> is maintained at the pre-determined level V_{SL}. Furthermore, since the set and the reset operations are executed simultaneously, the write time of the cell array 110 is reduced.

FIG. 3B is a schematic diagram of a verify operation according to an embodiment of the present invention. The word line WL<0> is at a turn-on level V_{ON1} to identify the data stored in the cells M₀₀˜M₀₃. In this embodiment, when the verify operation is executed, the level of the source line SL<0> is also maintained at the pre-determined level V_{SL}. At this time, each of the bit lines BL<0>˜BL<3> is at a read level V_{VRF1}. In this embodiment, the read level V_{VRF1} is higher than the pre-determined level V_{SL}. Therefore, the current paths 340, 350 and 360 are formed in the cells M₀₀, M₀₂ and M₀₃. The current in the current path 340 flows from the variable resistor R₀₀ to the transistor T₀₀. The current in the current path 350 flows from the variable resistor R₀₂ to the transistor T₀₂. The current in the current path 360 flows from the variable resistor R₀₃ to the transistor T₀₃. In one embodiment, the current in the current path 340 is greater than each of the currents in the current paths 350 and 360. The current in the current path 340 may be 10 uA and the current in the current path 350 or 360 may be 1 uA. In this embodiment, the resistances in the cells M₀₀˜M₀₃ are obtained according to the currents in the current paths 340, 350 and 360, and the data stored in the cells M₀₀˜M₀₃ are identified according to the resistances of the cells M₀₀˜M₀₃.

FIG. 4A is a schematic diagram of a set operation and a reset operation according to another embodiment of the present invention. FIG. 4A is similar to FIG. 3A with the exception that the source line SL<0> is maintained at a ground level GND. Since the level of the source line SL<0> is between the setting level V_{SET2} and the reset level V_{RESET2}, it is obtained that the setting level V_{SET2} is a positive level and the reset level V_{RESET2} is a negative level. In one embodiment, the difference between the setting level V_{SET2} and the ground level GND is the same as the difference between the reset level V_{RESET2} and the ground level GND.

Since the level of the word line WL<l> is a turn-off level V_{OFF2}, the transistors T₁₀˜T₁₃ in the cells M₁₀˜M₁₃ are turned off. In one embodiment, the turn-off level V_{OFF2} is equal to the reset level V_{RESET2}. In another embodiment, the turn-off level V_{OFF2} is less than the turn-off level V_{OFF1}. In some embodiments, the turn-on level V_{ON2}, the setting level V_{SET2}, and the reset level V_{RESET2} in FIG. 4A are less than the turn-on level V_{ON1}, the setting level V_{SET1}, and the reset level V_{RESET1} in FIG. 3A, respectively. Therefore, the transistors T₀₀˜T₁₃ are not high-voltage elements with large sizes, and the usable space of the memory device is increased and the cost of the memory device is reduced. In this embodiment, the current in the current path 410 flows from the variable resistor R₀₀ to the transistor T₀₀, the current in the current path 420 flows from the transistor T₀₂ to the variable resistor R₀₂, and the current in the current path 430 flows from the transistor T₀₃ to the variable resistor R₀₃.

FIG. 4B is a schematic diagram of a verify operation according to another embodiment of the present invention. The word line WL<0> is at the turn-on level V_{ON2} to identify the data stored in the cells M₀₀˜M₀₃. In this embodiment, during the execution of the verify operation, the source line SL<0> is also at the ground level GND. At this time, each of the bit lines BL<0>˜BL<3> is at a read level V_{VRF2}. In this embodiment, the read level V_{VRF2} is less than the read level V_{VRF1}. Furthermore, the current of each of the current paths 440, 450 and 460 flows from the variable resistor to the transistor.

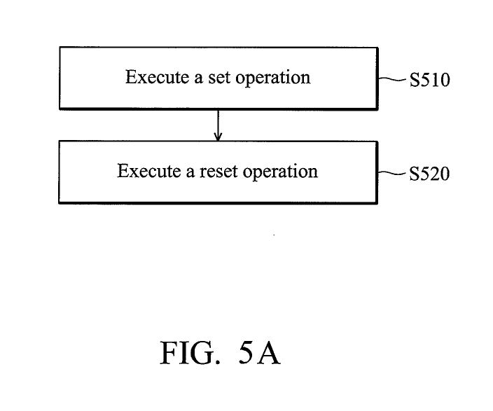

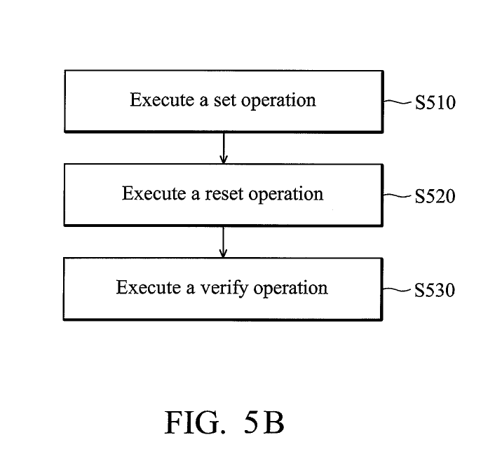

FIG. 5A is a flowchart of a control method according to an embodiment of the present invention. The control method is utilized in a resistive memory device. In one embodiment, the resistive memory device comprises a first cell and a second cell. The first cell is coupled to a word line, a first bit line and a source line. The second cell is coupled to the word line, a second bit line and the source line.

A set operation is executed (step S510). Assume that the set operation is executed for the first cell. In one embodiment, a turn-on level is provided to the word line, a setting level is provided to the first bit line, and a pre-determined level is provided to the source line. After executing the set operation, the first cell has a first resistance, such as a low resistance.

A reset operation is executed (step S520). Assume that the reset operation is executed for the second cell. In one embodiment, the turn-on level is provided to the word line, a reset level is provided to the second bit line and the pre-determined level is provided to the source line. In this case, after executing the reset operation, the second cell has a second resistance, such as a high resistance. During the executions of the set and the reset operations, the same level is provided to the source line. Therefore, the level of the source line does not need to be adjusted, and the write time of the resistive memory device is reduced.

In one embodiment, steps S510 and S520 are simultaneously executed. In another embodiment, the reset level is less than the setting level. In this embodiment, the pre-determined level is between the setting level and the reset level. In one embodiment, the reset level is a ground level.

In another embodiment, the pre-determined level is the ground level. In this case, the reset level is a negative level. In some embodiments, if a specific cell does not need to be set or reset, the pre-determined level is provided to the corresponding bit line coupled to the specific cell. In one embodiment, the specific cell is disposed between the first and the second cells.

FIG. 5B is a flowchart of a control method according to another embodiment of the present invention. FIG. 5B is similar to FIG. 5A except for the addition of step S530. Step 530 is to execute a verify operation. In one embodiment, step S530 is to detect the resistance of the first cell and compare the detected result with a reference resistance. In another embodiment, each of the first and the second cells comprises a first sub-cell and a second sub-cell. Taking the first sub-cell as an example, step S530 is to read the resistances of the first and the second sub-cells and obtain the data stored in the first cell according to the read result.

In some embodiments, during the verify operation, the turn-on level is provided to the word line, a read level is provided to the first and the second bit lines and a pre-determined level is provided to the source line to detect the resistances of the cells. In one embodiment, the read level is higher than the pre-determined level, but the disclosure is not limited thereto. When the verify operation is executed, the same pre-determined level is provided to the source line. Therefore, the level of the source line does not need to be adjusted, the read time of the resistive memory device is reduced.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

1. A resistive memory device, comprising:
a first cell coupled to a word line, a first bit line and a source line;
a second cell coupled to the word line, a second bit line and the source line; and
a control circuit controlling levels of the word line, the first bit line and the source line to execute a set operation for the first cell such that the first cell has a first resistance, and controlling levels of the word line, the second bit line and the source line to execute a reset operation for the second cell such that the second cell has a second resistance greater than the first resistance,
wherein during the execution of the set operation, the control circuit asserts the level of the source line at a pre-determined level and during the execution of the reset operation, the control circuit asserts the level of the source line at the pre-determined level,
wherein the pre-determined level is a ground level and the control circuit simultaneously executes the set and reset operations.

2. (canceled)

3. The resistive memory device as claimed in claim 1, wherein during the executions of the set and the reset operations, the control circuit asserts the first bit line at a setting level and asserts the second bit line at a reset level lower than the setting level.

4. The resistive memory device as claimed in claim 3, wherein the pre-determined level is between the setting level and the reset level.

5. (canceled)

6. The resistive memory device as claimed in claim 1, wherein the control circuit controls the levels of the word line, the first bit line, the second bit line and the source line to execute a verify operation to read the first and the second resistances, and during the execution of the verify operation, the level of the source line is the pre-determined level.

7. The resistive memory device as claimed in claim 1, wherein during the execution of the verify operation, the levels of the first and the second bit lines are the same.

8. The resistive memory device as claimed in claim 7, wherein the control circuit comprises a sensing amplifier unit, and during the execution of the verify operation, the sensing amplifying unit compares the first resistance with a reference resistance to identify data stored in the first cell.

9. The resistive memory device as claimed in claim 7, wherein the first cell comprises a first sub-cell and a second sub-cell, the control circuit comprises a sensing amplifying unit, and during the execution of the verify operation, the sensing amplifier unit reads resistances of the first and the second sub-cells to identify data stored in the first cell.

10. The resistive memory device as claimed in claim 1, further comprising:
a third cell coupled to the word line, a third bit line and the source line, wherein the third bit line is disposed between the first and the second bit lines, when the control circuit executes the set operation or the reset operation, the control circuit asserts a level of the third bit line at the pre-determined level, and no current path is formed in the third cell for no operation of the selected third cell.

11. A control method for a resistive memory device comprising a first cell and a second cell, wherein the first cell is coupled to a word line, a first bit line and a source line and the second cell is coupled to the word line, a second bit line and the source line, the control method comprising:
executing a set operation such that the first cell has a first resistance, wherein the set operation comprises:
providing a pre-determined level to the source line;
executing a reset operation such that the second cell has a second resistance higher than the first resistance, wherein the reset operation comprises:
providing the pre-determined level to the source line,
wherein the pre-determined level is a ground level and the set and reset operations are simultaneously executed.

12. (canceled)

13. The control method as claimed in claim 11, wherein when the set and the reset operation are executed, a setting level is provided to the first bit line and a reset level is provided to the second bit line, and the reset level is lower than the setting level.

14. The control method as claimed in claim 13, wherein the pre-determined level is between the setting level and the reset level.

15. (canceled)

16. The control method as claimed in claim 11, further comprising:
executing a verify operation to detect the first and second resistances, wherein the verify operation comprises:
providing the pre-determined level to the source line.

17. The control method as claimed in claim 16, wherein the verify operation comprises:
providing a reading level to the first and the second bit lines.

18. The control method as claimed in claim 17, wherein the verify operation comprises:
comparing the first resistance with a reference resistance.

19. The control method as claimed in claim 17, wherein the first cell comprises a first sub-cell and a second sub-cell, the verify operation is to read resistances of the first sub-cell and the second sub-cell and identifying the data stored in the first cell according to the read reset.

20. The control method as claimed in claim 11, wherein the resistive memory device further comprises a third cell coupled to the word line, a third bit line and the source line, the third bit line is disposed between the first and second bit lines, when the set operation or the reset operation is executed, and the pre-determined level is provided to the third bit line.
